(19) United States
(12) Patent Application Publication
(10) Pub. No.: US 2017/0260651 A1
(43) Pub. Date: Sep. 14, 2017

(54) Gallium Nitride Growth on Silicon

(71) Applicant: InnoSys, Inc., Salt Lake City, UT (US)

(72) Inventors: Joshua A. ROBINSON, Spring Mills, PA (US); Joan M. REDWING, State College, PA (US); Laurence P. SADWICK, Salt Lake City, UT (US); Jarod Christopher GAGNON, Salt Lake City, UT (US)

(21) Appl. No.: 15/529,118

(22) PCT Filed: Nov. 23, 2015
(86) PCT No.: PCT/US2015/062230

§ 371 Date: May 24, 2017

Related U.S. Application Data
(60) Provisional application No. 62/083,830, filed on Nov. 24, 2014.

(51) Int. Cl. C30B 29/40; H01L 21/20; H01L 29/778

(52) U.S. Cl. CPC C30B 29/406; H01L 29/778; H01L 21/2003

(57) ABSTRACT

Systems and methods for gallium nitride growth on silicon. A semiconductor device, comprising a silicon (001) substrate. A graphene layer on the silicon (001) substrate, wherein the graphene layer is synthesized without a metallic catalyst, and a gallium nitride-based layer over the graphene layer. Methods for growing a gallium nitride layer on silicon are also taught.

### BACKGROUND

The potential advantages of GaN-based devices for, for example among other but not limited to, power switching and light emitting diode (LED) and laser applications have been known for some time, and in recent times there has been a resurgence of interest in using alternative substrates to sapphire and silicon carbide (SiC) as a result of the potential to produce these devices at significantly reduced cost on large area Si substrates. Silicon provides good thermal conductivity for power devices, however, the differences in lattice constant and coefficient of thermal expansion (CTE) between GaN and Si gives rise to a high density of threading dislocations (TDs) and tensile stress in the film which is relaxed via the formation of channeling cracks. The film cracking problem has been ameliorated through the use of various transitions layers such as AlN and SiN interlayers, AlN/GaN superlattices and compositionally graded AlₓGa₁₋ₓN layers. The transition layer introduces compressive stress into the structure which partially off-sets the tensile CTE stress and induces the bending of edge-type TDs which reduces TD density. While this approach has been very successful at eliminating cracking in GaN layers up to a few microns in thickness, the growth of thicker (>5 μm) layers which are required to achieve high breakdown voltages (>1000V) and also for flexibility remains a challenge, particularly over large substrate areas.

### BRIEF DESCRIPTION OF THE DRAWINGS

A further understanding of the various exemplary embodiments may be realized by reference to the figures which are described in remaining portions of the specification. In the figures, like reference numerals may be used throughout several drawings to refer to similar components.

FIG. 1 depicts two possible atomic arrangements of (0001) AlN on the (001) Si surface.

FIG. 2 depicts schematic of the direct growth of graphene on Si(001) for the utilization of graphene/Si(001) as a multifunctional substrate in vertical GaN device architectures in accordance with some embodiments of the invention.

FIG. 3 depicts a schematic of a metalorganic chemical vapor deposition (MOCVD) reactor with multibeam optical stress sensor (MOSS) system that can be used for in-situ stress measurements.

FIG. 4 depicts stress-thickness versus film thickness curve measured during GaN growth on (111)Si using an AlN buffer layer. Positive and negative slopes indicate tensile and compressive film stress, respectively.

FIGS. 5A-5B depict an example of data obtained from MOSS measurement during MOCVD growth of Al_{0.44}G_{a0.56}N/AlN growth on SiC. FIG. 5A depicts reflected laser intensity and substrate curvature as a function of time during growth. FIG. 5B depicts stress thickness versus film thickness plot for Al_{0.44}Ga_{0.56}N layer demonstrating a compressive to tensile stress transition during growth.

FIG. 6 depicts a stress-thickness curve obtained during MOCVD growth for GaN grown on (111) Si with graded AlₓGa₁₋ₓN layer to induce dislocation bending and annihilation. Positive and negative slopes indicate tensile and compressive film stress, respectively. Stress transitions from tensile to compressive during growth of the graded AlₓGa₁₋ₓN layer which reduces film cracking.

FIG. 7 depicts an X-ray diffraction scan of an LED device structure, and specifically a 2 Theta-omega scan of the multiple quantum well (MQW) device showing that GaN is substantially or entirely c-axis oriented.

FIG. 8 is a plot of an example of the photoluminescence of GaN and InGaN grown on Si(001) in accordance with one or more embodiments of the invention.

FIG. 9 is a cross-section diagram of an InGaN/GaN MQW structure in accordance with one or more embodiments of the invention.

FIG. 10 is a cross-section diagram of an InGaN/GaN LED structure in accordance with one or more embodiments of the invention.

FIGS. 11-14 depict methods for growing GaN based materials on a substrate using graphene in accordance with one or more embodiments of the invention.

### DESCRIPTION

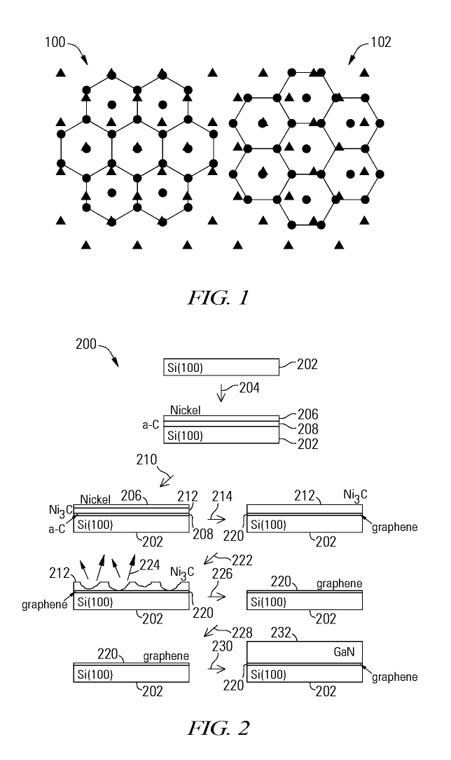

The drawings and description, in general, disclose systems and methods for gallium nitride growth on silicon. As a result of the crystalline symmetry, GaN epitaxy is typically carried out on (111) Si substrates. However, the use of large area, low cost (001) Si offers the intriguing potential to seamlessly integrate Si electronics and processing technology with GaN-based devices. For example, high performance DC power converters can be realized by combining high voltage AlGaN/GaN power switches with lower voltage Si power MOSFETs and integrated optoelectronic devices, structures, systems, etc. including but not limited to LED and/or laser based devices with silicon electronics can be realized. A structure of this type has been demonstrated on (001) Si using a wafer bonding approach, however, this involved multiple bonding and etch-back steps which pose difficulties in scale-up to large areas. The direct epitaxial growth of GaN on (001) Si is therefore highly desirable but poses significant challenges to heteroepitaxy. The (001) Si surface has fourfold symmetry as compared to the sixfold symmetry of the (0001) plane of wurtzite GaN. It has been demonstrated that (0001) AlN grows on (001) Si with two preferred rotational alignments 100, 102 (See FIG. 1) which results in poor island coalescence, high TD density and increased surface roughness. The key to obtaining single crystal GaN on (001) Si, therefore, is to suppress one of the rotational alignments of the AlN nuclei over the other which in turn should reduce the TD density. One approach which has been successful both for the growth of GaN and other III-V materials on (001) Si is to use miscut substrates. In the case of GaN growth, misorientation of the substrate produces biatomic steps on the Si surface which alter the rotational alignment of the AlN nuclei. An AlGaN/GaN HEMT structure with a TD density of 2×10¹⁰ cm⁻² and a sheet resistance of 350 Ω/sq was recently demonstrated using (001) Si misoriented 6° toward the [110] direction. The total epitaxial thickness in this case was ˜2 μm, consequently, further reductions in TD density can be anticipated for thicker layers. A significant drawback to the use of misoriented substrates is the high surface roughness which is typically obtained due to the formation of macrosteps during growth.

In addition to growth on (001) Si, there is also the need for vertical GaN-on-Si structures in which the Si substrate plays a functional role in the device. This requires either direct epitaxial growth of GaN on Si or the development of highly conductive buffer layer strategies that introduce minimal series resistance. The direct growth of GaN on Si at high temperatures is challenging due to the formation of a Ga—Si liquid alloy which generates surface pits via melt-back etching of the Si at elevated temperatures. As a result, AlN is widely employed as an initial nucleation layer for GaN growth on Si, however, the high resistivity of AlN is problematic for the realization of vertical devices structures. Conductive nucleation and transition layers are therefore required that enable the growth of high quality GaN epilayers without the introduction of undesired high resistivity layers. In addition, being able to have heteroepitaxial GaN-based devices with Si-based devices and integrated circuits including but not limited to complementary metal oxide semiconductor (CMOS) devices, circuits, integrated circuits is of great value.

An embodiment of the present invention comprises an InGaN-GaN light emitting diode (LED) on CMOS-compatible (001) Si substrates. The present invention involves the materials growth and processing technologies to enable the fabrication of high crystalline quality, crack-free GaN epilayers on (001) Si substrates with conductive buffer layers that enable realization of true vertical GaN-on-Si devices. This is accomplished in a multi-stage approach that addresses the key challenges of stress mediation and TD reduction in GaN on Si epitaxy along with development of novel methods to integrate device layers on (001)Si. As an example, the nitride-based materials growth can be carried out in a group III-nitride MOCVD reactor that, for example, incorporates an in-situ wafer curvature measurement system for real time monitoring of film stress and growth rate. The use of graphene formed on (001) Si can be used as a template layer for GaN epitaxy. Graphene templates can be fabricated using two different processes. The first process utilizes a highly-scalable metal-mediated synthesis method for direct formation of GaN on graphene. The second process uses a method for transfer of CVD grown graphene from copper growth substrates to (001) Si. Conductive, strain mitigating buffer layer utilizing Si-doped GaN and AlGaN transition layers which significantly reduce TD density and provide thick crack-free epilayers can be used as part of the present invention. GaN epilayers with suitable material quality can be produced on the graphene/(001)Si substrates to fabricate p-GaN/InGaN/n-GaN epilayers and devices such as LEDs and transistors.

Synthesis of high conductivity graphene as a growth template for GaN-based vertical devices on Si(001). The development of a high quality growth template for gallium nitride epitaxial layers on silicon (001) has been a goal of many research efforts for more than a decade, however it has been met with limited success. However the use of a relatively unique material—graphene—as a novel template for GaN epitaxy on arbitrary substrates provides the possibilities of achieving the growth of GaN-based materials on (001)Si substrates. Graphene templates offer several advantages for group III-nitride epitaxy. The hexagonal atomic arrangement of carbon atoms in graphene is crystallographically compatible with the wurtzite phase of GaN. Furthermore, several methods exist to either transfer or directly fabricate graphene on a variety of substrates such as Si and glass. However, there are significant challenges associated with GaN epitaxy on graphene. The surface energy of graphene is significantly different than that of sapphire, SiC, Si or other common substrates used for GaN growth. This results in differences in the wetting behavior of AlN and GaN on graphene which impact film nucleation and growth. In addition, the graphene surface often contains wrinkles, grain boundaries and other defects which impact the growth process.

Wafer scale graphene can be implemented using a variety of synthesis techniques, such as, but not limited to: silicon sublimation from SiC (epitaxial graphene), catalytic chemical vapor deposition (CVD), and non-catalytic CVD. Synthesis from SiC, while highly scalable, does not provide a route to a high quality template for GaN synthesis on Si(001). On the other hand, CVD of graphene works on a variety of metal substrates, including nickel, iridium, ruthenium, platinum, and copper, but the required layer transfer is non-ideal for high-performance epitaxial template applications due to microcracking, interfacial contamination between graphene and the overlaying epitaxial layer, and the generation of unintentionally doped regions of graphene from the metal etchant. As a result, the synthesis of graphene films without a metallic catalyst can be an excellent route for the development of a high quality growth template.

In addition the use of epitaxial graphene which offers a higher quality template than CVD grapheme can also be used with the present invention. Embodiments of the present invention can transfer epitaxial graphene to (001)Si.

As an example of an implementation of the present invention, graphene was used as a template layer for the growth of GaN and GaN/InGaN MQW and LED device structures on (001)Si substrates. The substrates were prepared with CVD graphene transferred onto oxidized (001)Si substrates. A further embodiment of the present invention can utilize a two-step AlN buffer layer growth process to enable growth of c-axis oriented GaN grains on the CVD graphene. Using such embodiments, InGaN MQW and LED structures were fabricated on the CVD graphene substrates.

As part of one example embodiment of the present invention, large scale epitaxial graphene on (0001) oriented, semi-insulating 6H-SiC through combination of sublimation and hydrogen intercalation leading to carrier mobilities as high as 3000 cm²/V·sec at 10¹³ cm⁻² can be produced. Hydrogen intercalation is a key step in maintaining high carrier mobility for epitaxial graphene because it eliminates the interface layer between graphene and SiC, and therefore reduces a major source of scattering. The presence of step bunching in the SiC substrate is linked to degraded performance, which can be ameliorated to improve performance in graphene materials. Various embodiments of the invention enable direct synthesis of graphene on silicon. This should not be viewed as limiting in any way or form for the present invention,

Some embodiments of the present invention use a unique method of graphene synthesis that utilizes the dissolution of amorphous carbon in a thin nickel film, followed by quenching to form a high quality graphene layer directly on Si(001) without the typical intermetallic reactions that can occur when utilizing silicon substrates for graphene synthesis. FIG. 2 depicts a generalized schematic 200 for a low-cost, highly scalable method of graphene synthesis directly on Si(001) in accordance with one or more embodiments of the invention. In an early step 204, the method includes deposition of 10-20 nm of amorphous carbon (a-C) 208 and 50 nm of high purity nickel (Ni) 206 on a Si(001) substrate 202. (Notably, any measurements of thickness, time, temperature or of any other quantity disclosed herein are merely examples and are not limiting values.) Deposition of the carbon layer 208 before the nickel layer 206 provides a means to eliminate silicon/Ni intermetallic compounds that would degrade GaN device performance. Following deposition of the layers, in another step 210 a rapid thermal treatment at 900-1025° C. for 5 min is used to form a solid solution of nickel and carbon, as well as an intermetallic Ni₃C 212. Upon quenching, carbon that is in solid solution precipitates to the Ni₃C/Si(001) interface forming graphene 220 (see step 214). Subsequently, the sample is heated (see step 222) to >1025° C., which results in vaporization 224 of the Ni₃C 212, and the remaining structure is a high quality graphene/Si(001) template 220 (see step 226) that can be functionalized (see step 228) for GaN 232 synthesis (see step 230).

In addition to the direct growth of graphene on Si(001), functionalization schemes that include nitrogen doping and ammonia treatments to enhance the interaction between GaN and graphene as a means to promote a low resistance interface for device operation can also be used. The functionalization process will yield nitrogen terminated surface, ideal for subsequent synthesis of GaN epitaxial layers. In addition to functionalizing the graphene for GaN synthesis, GaN, in some embodiments of the present invention, nucleate preferentially at multilayer graphene ridges on non-functionalized graphene. Therefore the nucleation and growth characteristics of GaN films on non-functionalized graphene with variations in step-edge and defect density can also be employed. GaN can be nucleated preferentially on step-edges and defects in the graphene layer.

Growth of GaN epitaxy on graphene/(001)Si substrates: GaN epitaxy on graphene/(001)Si includes having a working understanding of how AlN and GaN nucleate on graphene layers. GaN can also nucleate on graphene layers deposited on sapphire substrates. It was reported that GaN preferentially nucleated at multi-layer graphene ridges. Step-edge and defect density in graphene on the nucleation of AlN and GaN can be used. By varying the density of step-edges and defects in graphene the density of AlN and GaN nuclei formed at these defects can be tailored. The effect of the graphene thickness (i.e. the number of graphene layers) on AlN and GaN nucleation can be used to implement the optimal graphene buffer layer conditions for subsequent AlN and GaN growth on Si(001). The differences between the two graphene deposition methods (transfer of CVD graphene and direct graphene deposition using a Ni layer) on GaN nucleation can be optimized and exploited in embodiments of the present invention. The effect of graphene thickness, step-edge, and defect density can also be used to determine the optimal graphene growth conditions for the nucleation of c-axis oriented, wurtzite GaN nuclei. After these conditions have been obtained, growth of coalesced GaN films on graphene layers can be performed such that the graphene buffer layer is used to affect the stress state of the GaN film.

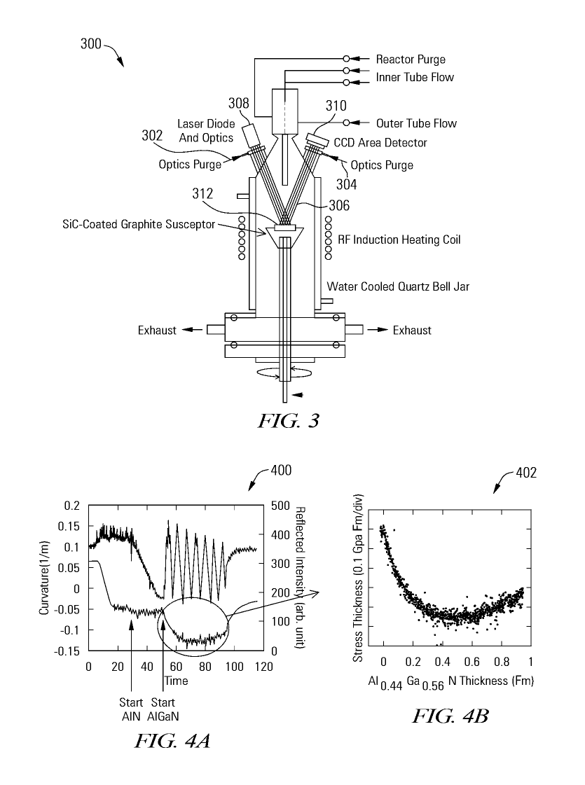

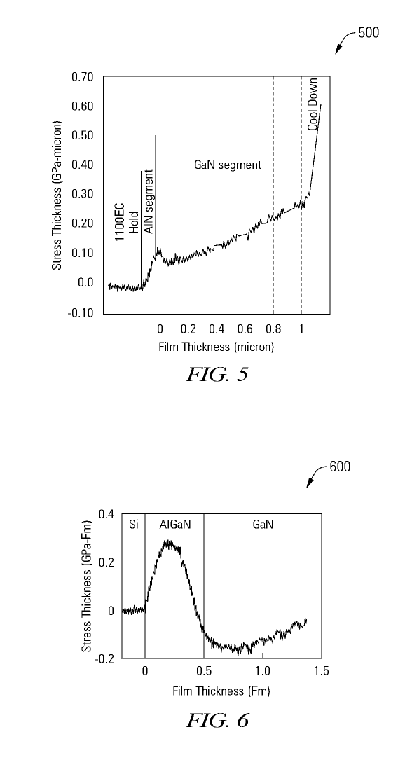

The GaN layers can be grown by metalorganic chemical vapor deposition (MOCVD) in a system that, for example, but not limited to, incorporates a laser reflectance tool for real-time measurements of wafer curvature during growth. Such a system can be used to carry out detailed studies of stress evolution during GaN growth on (111) Si. In-situ wafer curvature measurements are an essential tool in the development of GaN-on-Si epitaxy. An example MOCVD reactor 300, shown schematically in FIG. 3, is equipped with purged optical ports 302, 304 and a multibeam optical stress sensor (MOSS) system. This system uses a linear array of parallel laser beams 306 from laser diodes and optics 308 and a high resolution CCD camera 310 to provide information on curvature of a sample 312 as a function of time. Changes in sample curvature induce a proportional change in beam spacing on the CCD camera. The stress-thickness product (σ_{f}h_{f}) of the thin film is related to the sample curvature (κ) by Stoney's equation:

$${σ}_{f} {h}_{f} = \frac{{M}_{S} {h}_{s}^{2}}{6} κ \qquad ( Eq 1 )$$

where h_{f} and hₛ are the film and substrate thickness, respectively and Mₛ is the substrate biaxial modulus. An example of the data obtained from the MOSS system during MOCVD growth of Al_{0.44}Ga_{0.56}N/AlN/SiC structure is shown in the plot 400 of FIG. 4A. Information on film thickness and surface roughness, as well as nucleation and coalescence, can be obtained by monitoring the intensity of a reflected laser beam as a function of time. The film thickness can be determined by using a virtual interface model to fit the Fabry-Perot interference data. Consequently, information on intrinsic growth stress (σ_{f}) can be obtained by plotting the stress-thickness product (σ_{f}h_{f}) as a function of h_{f} as shown in the plot 402 of FIG. 4B. For films growing under a constant stress, the stress thickness-vs.-thickness plot is a straight line and the magnitude of the stress is obtained from the slope of the line. For films in which the stress changes with thickness, such as that shown in FIG. 4B, the incremental stress or slope of the stress-thickness vs. thickness curve will change. In this type of a plot, the slope is positive for tensile stress and negative for compressive stress. For the case of Al_{0.44}Ga_{0.56}N growth shown in FIG. 4B, the growth initiates under a compressive stress which results from epitaxial mismatch. The compressive stress relaxes with increasing film thickness eventually transitioning to a tensile stress.

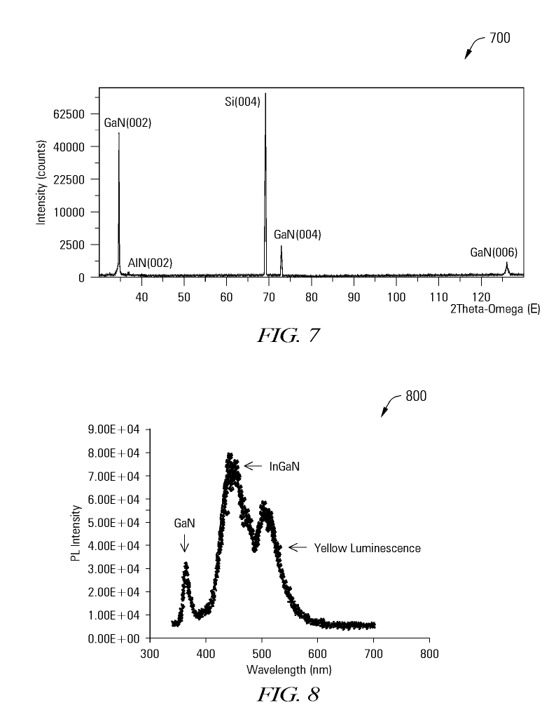

This approach can be used to study and set the parameters of GaN epitaxy on Si substrates using a variety of interlayer and transition layer approaches. The stress-thickness data shown in the plot 500 of FIG. 5 obtained for GaN growth on (111) Si using a thin AlN nucleation layer illustrates the essential problem that limits the growth of thick GaN layers. The GaN epilayer initiates growth on the AlN layer under a small compressive stress which results from epitaxial mismatch, but this rapidly transitions to a tensile growth stress as demonstrated by the positive slope of the stress-thickness plot. The tensile growth stress arises from the initial GaN island coalescence process as well as the inclination of edge-type TDs. Additional tensile stress is introduced into the GaN during cooling from the growth temperature to room temperature due to coefficient of thermal expansion (CTE) mismatch as demonstrated by the large change in curvature that occurs during cool-down. The combination of tensile growth stress and tensile stress from CTE mismatch results in significant tensile strain in the GaN epilayer which relaxes via the formation of channeling cracks.

Compositionally graded AlₓGa₁₋ₓN layers have successfully been employed between the AlN nucleation layer and the GaN epilayer to modify stress, film cracking and dislocation density in GaN on Si epitaxy. The plot 600 of FIG. 6 shows that the growth stress transitions from tensile to compressive can be obtained as the AlₓGa₁₋ₓN fraction is linearly decreased. The compressive stress in the AlₓGa₁₋ₓN layer compensates for the tensile CTE stress and also induces the bending of edge-type threading dislocations resulting in reduced TD density in the GaN epilayer. This approach can be used to grow GaN epilayers as thick as 3 μm on (111) Si with threading dislocation density in the range of 10⁹-10¹⁰ cm⁻³ that do not exhibits cracks after growth or sample dicing.

Development of conductive, strain-mitigating buffer layers for GaN-on-Si: The implementation of a conductive buffer layer methodology for GaN on (001)Si can be employed in the present invention. As mentioned previously, the direct growth of GaN on Si at high temperatures is challenging due to the formation of a Ga—Si liquid alloy which generates surface pits via melt-back etching of the Si at elevated temperatures. As a result, AlN is widely employed as an initial nucleation layer for GaN growth on Si, however, the high resistivity of AlN is problematic for the realization of a number of types of structures and devices including but not limited to vertical devices structures. In some embodiments, conductive nucleation and transition layers are used that enable the growth of high quality GaN epilayers without the introduction of undesired high resistivity layers. A similar problem is encountered in the heteroepitaxial growth of GaN on SiC where AlN is commonly employed to improve wetting and act as a nucleation layer. In this case, however, it has proven feasible to utilize heavily n-type doped AlₓGa₁₋ₓN layers fabricated with low Al fractions (x<0.1) along with compositional grading of the layers to form low resistivity buffer layers that have enabled the realization of vertical GaN-on-SiC devices including LEDs and p-i-n diodes. The extension of this approach to Si substrates is more complicated given the problem of melt-back etching and the need to utilize the AlGaN both as a nucleation layer and as a strain mediating layer to reduce film cracking. However, H-termination of the Si surface, achieved through the use of high H₂ partial pressures at the start of growth, can successfully suppress Ga—Si liquid alloy formation. Therefore some embodiments of the present invention utilize an AlGaN strain-mitigating layer in order to build in compressive stress from the epitaxial mismatch between GaN and AlN within the epilayer structure to offset the CTE mismatch between GaN and Si. However, compressive stress induces the bending of TDs which relaxes the compressive stress and can even generate additional tensile stress. Consequently, it is beneficial to achieve the lowest possible TD density at the start of growth in order to retain the maximum compressive stress within the layer structure. Intentional Si doping can also induce the inclination of TDs even in films that grow under a tensile stress. Therefore the use of heavy Si doping in the initial AlGaN transition layer which grows under a tensile stress as a route to promote the bending and annihilation of TDs as well as to obtain a conductive buffer layer structure can be employed. Once the film stress has transitioned from tensile to compressive as shown in FIG. 6(b), the Si doping can be stopped to inhibit further dislocation bending. The effect of Si doping level, AlGaN composition and layer thicknesses on film stress and microstructure can be used to optimize the properties and performance and to also reduce the TD density and mediate the tensile stress to achieve thick crack-free layers.

A secondary layer structure that utilizes Si-doped GaN to lower the TD density and AlGaN interlayers to induce compressive stress can also be used. Previous studies have presented a stress-mitigating layer structure for GaN growth on Si(111) which utilized a Si-doped GaN layer followed by a thin AlN interlayer. TD densities on the order of ˜10⁸ cm⁻² and no channeling cracks were observed in final GaN films up to 1 μm thick when using this layer structure. The Si-doped GaN layer causes inclination of TDs at early stages of the growth process, resulting in annihilation of neighboring dislocations and a reduction in the TD density. The thin AlN layer then induces a compressive stress in the GaN film, with minimal relaxation during growth due to the reduced TD density in the film. A similar modified approach for GaN grown on graphene can be used in order to obtain low dislocation density, crack free GaN. In some embodiments of the invention, heavily-doped AlGaN layers are utilized to induce compressive stress in the GaN film, instead of the previously used AlN layers, in order to obtain a conductive layer structure to mitigate stress in the GaN film.

Development of GaN-based LED device structures on Si(001): As another example, an InGaN-GaN LED on CMOS-compatible Si(001) can be generated. For example using GaN films on Si(001) with acceptable dislocation density, the growth of AlGaN/GaN heterostructures can be performed. Both N-type and p-type doped GaN films can be fabricated. Si-doping from a SiH₄ source is used in some embodiments to form n-type device layers. Biscyclopentadienyl magnesium (Cp₂Mg) can also be used as the Mg source for p-type doping of GaN layers for doping and InGaN growth, p-GaN/InGaN/n-GaN device layers can be grown on (001)Si. Low resistance metal contacts can be deposited on the p-type and n-type GaN layers.

Development of GaN-based power device structures and devices on Si(001): As yet another example, GaN-based power transistors and diodes on CMOS-compatible Si(001) can be obtained. For example using GaN films on Si(001) with acceptable dislocation density, the growth of GaN/InGaN/GaN heterostructures and quantum wells can be performed. N-type and p-type doped GaN films can be fabricated. Si-doping from a SiH₄ source can be utilized to form n-type device layers. Biscyclopentadienyl magnesium (Cp₂Mg) as well as carbon precursors can also be used as the Mg source for p-type doping of GaN layers for doping and growth, device layers can be grown on (001)Si. Low resistance metal contacts can be deposited on the p-type and n-type GaN layers. FIG. 7 shows an example 2 theta-omega (2θ-ω) x-ray diffraction result 700 of GaN grown on Si(100) using embodiments of the present invention, showing that GaN is substantially or entirely c-axis oriented.

Although MOCVD growth was discussed herein, other growth methods including, but not limited to, molecular beam epitaxy (MBE), gas source MBE (GSMBE), plasma assisted MBE (PAMBE), chemical beam epitaxy (CBE), atomic layer epitaxy (ALE), atomic layer deposition (ALD), hydride vapor phase epitaxy (HVPE), sputtering, pulsed laser deposition (PLD), electron beam evaporation, thermal evaporation and deposition, other chemical vapor deposition (CVD) and physical vapor deposition (PVD) methods, approaches, techniques, etc., other methods approaches, techniques, etc. known, etc. can be used to with and/or as part of embodiments of the present invention.

The present invention can allow for thinned downed/etched back power MOSFET structures essentially of any type including those discussed above and then growing a GaN epilayer on, for example, the etched back/thinned down (001) Si which is also written as (100) orientation Si to create and fabricate a Si power FET structure with, for example, a GaN epitaxial drift region. Such structures can then have an appropriate mechanical and electrical support structure or structures to enable the device to be completed and, for example, packaged. Band gap offsets also referred to as band offsets (i.e., conduction band and/or valance band offsets) can be used to support current transport; if desired additional steps and/or layers can be employed including, but not limited to, hetero-interfaces, superlattice(s), heavily doped layers, tunneling layers, tunnel junctions, etc., other processing steps and techniques, or combinations of these, etc. In addition, other methods including but not limited to wafer bonding, other types of bonding, attaching, epitaxial growth, regrowth, selective growth, diffusion blocking layers, chemical mechanical polishing (CMP), surfactants, templates, patterning, crystal orientation, layers, etc. can also be used. The present invention can use but is not limited to using chemical vapor deposition (CVD), metalorganic CVD (MOCVD), organometallic vapor phase epitaxy (OMVPE), atomic layer epitaxy (ALE), atomic layer deposition (ALD), migration-enhanced epitaxy (MEE), selective area growth, selective area epitaxy, molecular beam epitaxy (MBE), gas source molecular beam epitaxy (GSMBE), chemical beam epitaxy (CBE), plasma enhanced CVD (PECVD), plasma enhanced MBE (PEMBE), liquid phase epitaxy (LPE), selective epitaxy growth (SEG), selective area etching (SAE), epitaxial lateral overgrowth (ELO), vapor phase epitaxy (VPE) including all types of VPE such as hydride vapor phase epitaxy (HVPE), physical vapor deposition (PVD), electron beam evaporation, sputtering, sol gel processes, ink jet, screen printing, chemical etching, dry etching including reactive ion etching (RIE) and deep RIE (DRIE), etc., combinations of these, etc. to create, fabricate, etc., implementations and embodiments of the present invention. The term “create” is used herein to refer generically to any method or technique for growing, forming, depositing, fabricating, evaporating, etc. layers and/or structures in the device, and should not be interpreted as being limited to any particular technique.

The present invention can also be used to realize micro LEDs (μLEDs) and nano LEDs (nLEDs) that, for example, but, not limited to, can be used in displays and lighting including in television displays, cellular phone displays, tablets, other personal digital assistants, other hand held devices, projection systems, wearables, watches, smart watches, etc. Embodiments of the present invention can be used to create self-assembly mLEDs and/or nLEDs that can be self-assembled and aligned including but not limited to self-aligned and permit any number of colors of display (i.e., red, green, blue; red, green, blue, amber, white with red, green, blue and one or more white with red, green, blue, etc., combinations of these, etc.) including in combination with other types and forms of emissive or down-converting/up-converting, etc. technologies, techniques, etc. including but not limited to quantum dots, quantum dot LEDs, organic light emitting diodes (OLEDs), phosphors, phosphor-coatings, etc., combinations of these, etc. In addition, the present invention can be used in mini or any other size displays or lighting including solid state lighting and general lighting. Such self-assembly could be accomplished, for example, but not limited to, by using the graphene template and related layers/materials to form specific micro or nano LED structures that each have, for example, but are not limited to, a different shape to fit into a display grid, matrix, arrangement, etc. A plot 800 in FIG. 8 depicts an example of the photoluminescence of GaN and InGaN grown on Si(001) in accordance with one or more embodiments of the invention. The photoluminescence spectrum of the MQW shows a distinct peak for InGaN luminescence as well as GaN band-edge luminescence and yellow-band luminescence. The position of the InGaN PL peak corresponds to ˜13.7% In in the layer.

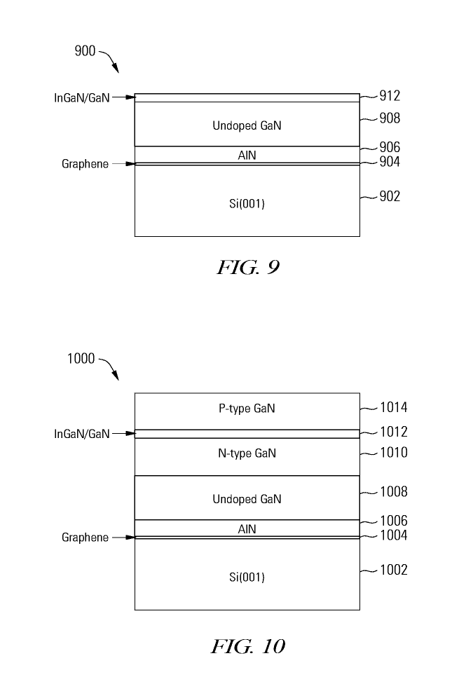

Turning to FIG. 9, a cross-section diagram 900 of an InGaN/GaN MQW structure is depicted in accordance with one or more embodiments of the invention. Layers depicted in the example MQW structure include, from substrate up, a Si(001) substrate 902, graphene layer 904, AlN layer 906, undoped GaN layer 906 grown in some embodiments for times ranging up to, for example but not limited to, minutes in order to fully cover the graphene 904 prior to GaN device structure growth, and an InGaN/GaN multi period superlattice layer 912.

Turning to FIG. 10, a cross-section diagram 1000 of an InGaN/GaN LED structure is depicted in accordance with one or more embodiments of the invention. Layers depicted in the example MQW structure include, from substrate up, a Si(001) substrate 1002, graphene layer 1004, AlN layer 1006, undoped GaN layer 1008 grown in some embodiments for, for example but not limited to, minutes in order to fully cover the graphene 1004 prior to GaN device structure growth, N-type doped GaN layer 1010, doped in some embodiments with Si, an InGaN/GaN multi period superlattice layer 1012, and a P-type doped GaN layer 1014, doped in some embodiments with Mg.

While illustrative embodiments have been described herein, it is to be understood that the concepts disclosed herein may be otherwise variously embodied and employed. The example embodiments disclosed herein illustrate certain features of the present invention and are not limiting in any way, form or function of the present invention. The present invention is, likewise, not limited in materials choices including semiconductor and substrate materials such as, but not limited to, silicon (Si), silicon carbide (SiC), silicon on insulator (SOI), other silicon combination and alloys such as silicon germanium (SiGe), etc., diamond, graphene, graphene oxide, gallium nitride (GaN) and GaN-based materials, aluminum nitride (AlN) and AlN-based materials, indium nitride (InN) and InN-based materials, gallium arsenide (GaAs) and GaAs-based materials, etc. The present invention can include any type of transistor or light emitting device (LED) including switching transistors, linear transistors and elements including, but not limited to, field effect transistors (FETs) of any type such as metal oxide semiconductor field effect transistors (MOSFETs) including either p-channel or n-channel MOSFETs of any type, junction field effect transistors (JFETs) of any type, metal emitter semiconductor field effect transistors, etc. again, either p-channel or n-channel or both, bipolar junction transistors (BJTs) again, either NPN or PNP or both, heterojunction bipolar transistors (HBTs) of any type, high electron mobility transistors (HEMTs) of any type, tunnel junction field-effect transistors (TFETs) of any type, unijunction transistors of any type, modulation doped field effect transistors (MODFETs) of any type, etc., again, in general, n-channel or p-channel or both, vacuum tubes including diodes, triodes, tetrodes, pentodes, etc. and any other type of switch, etc.

Integration and co-integration of radio frequency (RF), microwave, millimeter-wave (mm-wave), optical, opto-electronics, light emitting diodes (LEDs), solid state lasers, integrated circuits (ICs), application specific integrated circuits (ASICs), memory including but not limited to, FLASH, electrically erasable read only memory (EEPROM , E2PROM, etc.), programmable read only memory (PROM), random access memory (RAM), static random access memory (SRAM), high temperature electronics, etc. The present invention allows the integration of lateral and vertical devices including but not limited to GaN-related containing material (i.e., GaN, AlGaN, InGaN, InN, AlN, etc.) with Si-based power devices and ICs including but not limited to complementary metal oxide semiconductor (CMOS), SOI, n-channel MOS (NMOS), p-channel MOS (PMOS), doubly diffused MOS (DMOS), bipolar CMOS DMOS (BCD), etc.

The examples, illustrations, Figures and implementations contained within are not to be construed as limiting in any way or form.

The example embodiments disclosed herein illustrate certain features of the present invention and are not limiting in any way, form or function of present invention. The present invention is, likewise, not limited in materials choices including semiconductor materials such as, but not limited to, silicon (Si), silicon carbide (SiC), silicon on insulator (SOI), other silicon combination and alloys such as silicon germanium (SiGe), etc., diamond, graphene, graphene oxide, gallium nitride (GaN) and GaN-based materials, aluminum nitride (AlN) and AlN-based materials, indium nitride (InN) and InN-based materials, gallium arsenide (GaAs) and GaAs-based materials, diamond on Si, diamond on other substrates, etc.

The present invention can include many types of switching elements including, but not limited to, field effect transistors (FETs) such as metal oxide semiconductor field effect transistors (MOSFETs) including either p-channel or n-channel MOSFETs, junction field effect transistors (JFETs), metal emitter semiconductor field effect transistors (MESFETs), other double diffused MOSFETs and lateral diffused MOSFETs (LDMOS), etc. again, either p-channel or n-channel or both, high electron mobility transistors (HEMTs), tunnel junction field-effect transistors (TFETs), unijunction transistors, modulation doped field effect transistors (MODFETs), insulated gate bipolar transistor (IGBT), BCD devices including but not limited to transistors, other types of transistors, switches, structures, including but not limited to silicon controlled rectifiers, diodes, rectifiers, triacs, thyristors, etc. The present invention may also be applicable to certain types of hetero-interface or heterojunction bipolar transistors.

The following flow diagrams should not be viewed as limiting in any way or form, including, but not limited to, order of performance, exclusivity of steps, mandatory inclusion of steps, or details of performance of steps, etc.

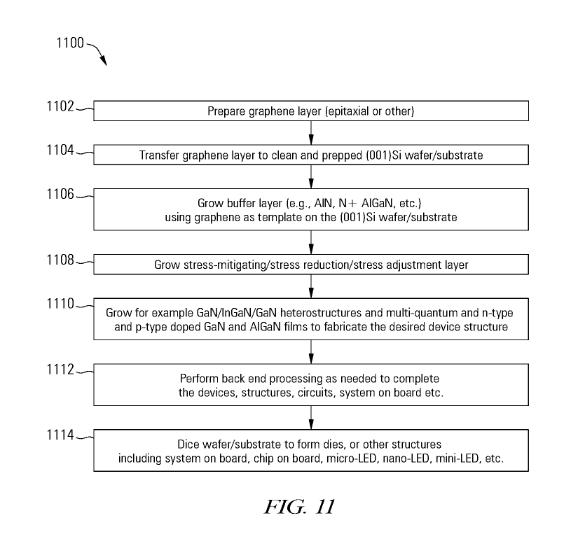

Turning to FIG. 11, an example operation for growing GaN based materials on a substrate using graphene is depicted in flowchart 1100 in accordance with one or more embodiments of the invention. Following flowchart 1100, the operation includes the following example steps, which are not necessarily limited to performance in this order. Prepare graphene layer (epitaxial or other). (Block 1102) Transfer graphene layer to clean and prepped (001)Si wafer/substrate. (Block 1104) Grow buffer layer (e.g., AlN, N+ AlGaN, etc.) using graphene as template on the (001)Si wafer/substrate. (Block 1106) Grow stress-mitigating/stress reduction/stress adjustment layer. (Block 1108) Grow for example GaN/InGaN/GaN heterostructures and multi-quantum and n-type and p-type doped GaN and AlGaN films to fabricate the desired device structure. (Block 1110) Perform back end processing as needed to complete the devices, structures, circuits, system on board etc. (Block 1112) Dice wafer/substrate to form dies, or other structures including system on board, chip on board, micro-LED, nano-LED, mini-LED, etc. (Block 1114)

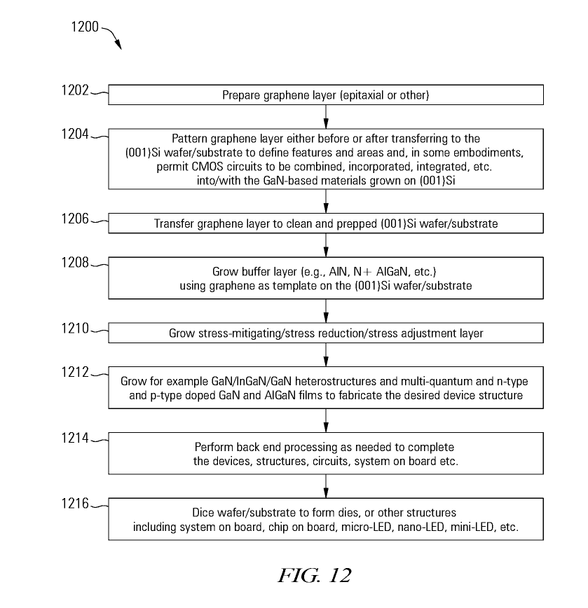

Turning to FIG. 12, an example operation for growing GaN based materials on a substrate using graphene is depicted in flowchart 1200 in accordance with one or more embodiments of the invention. Following flowchart 1200, the operation includes the following example steps, which are not necessarily limited to performance in this order. Prepare graphene layer (epitaxial or other). (Block 1202) Pattern graphene layer either before or after transferring to the (001)Si wafer/substrate to define features and areas and, in some embodiments, permit CMOS circuits to be combined, incorporated, integrated, etc. into/with the GaN-based materials grown on (001)Si. (Block 1204) Transfer graphene layer to clean and prepped (001)Si wafer/substrate. (Block 1206) Grow buffer layer (e.g., AlN, N+ AlGaN, etc.) using graphene as template on the (001)Si wafer/substrate. (Block 1208) Grow stress-mitigating/stress reduction/stress adjustment layer. (Block 1210) Grow for example GaN/InGaN/GaN heterostructures and multi-quantum and n-type and p-type doped GaN and AlGaN films to fabricate the desired device structure. (Block 1212) Perform back end processing as needed to complete the devices, structures, circuits, system on board etc. (Block 1214) Dice wafer/substrate to form dies, or other structures including system on board, chip on board, micro-LED, nano-LED, mini-LED, etc. (Block 1216)

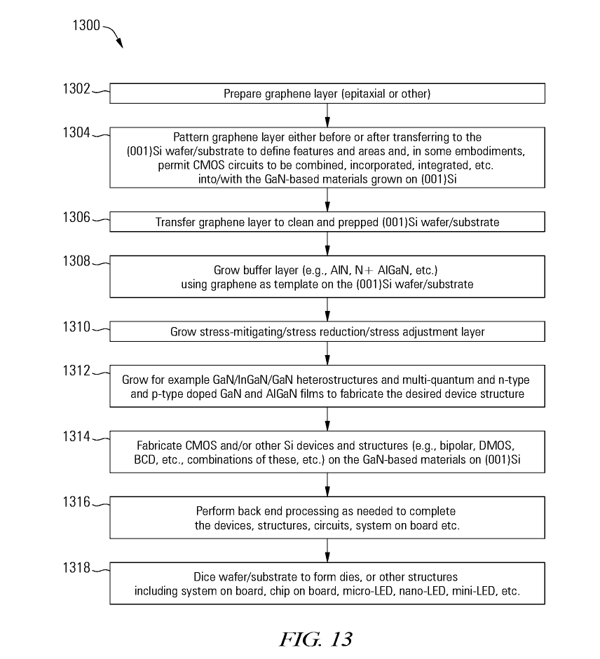

Turning to FIG. 13, an example operation for growing GaN based materials on a substrate using graphene is depicted in flowchart 1300 in accordance with one or more embodiments of the invention. Following flowchart 1300, the operation includes the following example steps, which are not necessarily limited to performance in this order. Prepare graphene layer (epitaxial or other). (Block 1302) Pattern graphene layer either before or after transferring to the (001)Si wafer/substrate to define features and areas and, in some embodiments, permit CMOS circuits to be combined, incorporated, integrated, etc. into/with the GaN-based materials grown on (001)Si. (Block 1304) Transfer graphene layer to clean and prepped (001)Si wafer/substrate. (Block 1306) Grow buffer layer (e.g., AlN, N+ AlGaN, etc.) using graphene as template on the (001)Si wafer/substrate. (Block 1308) Grow stress-mitigating/stress reduction/stress adjustment layer. (Block 1310) Grow for example GaN/InGaN/GaN heterostructures and multi-quantum and n-type and p-type doped GaN and AlGaN films to fabricate the desired device structure. (Block 1312) Fabricate CMOS and/or other Si devices and structures (e.g., bipolar, DMOS, BCD, etc., combinations of these, etc.) on the GaN-based materials on (001)Si. (Block 1314) Perform back end processing as needed to complete the devices, structures, circuits, system on board etc. (Block 1316) Dice wafer/substrate to form dies, or other structures including system on board, chip on board, micro-LED, nano-LED, mini-LED, etc. (Block 1318)

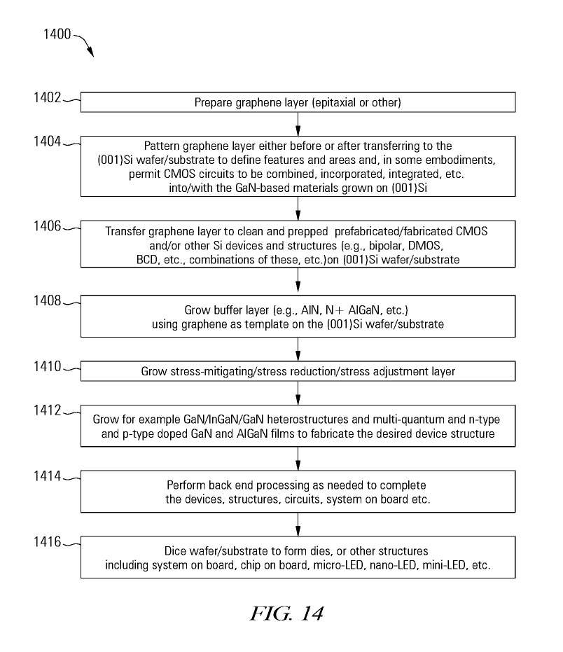

Turning to FIG. 14, an example operation for growing GaN based materials on a substrate using graphene is depicted in flowchart 1400 in accordance with one or more embodiments of the invention. Following flowchart 1400, the operation includes the following example steps, which are not necessarily limited to performance in this order. Prepare graphene layer (epitaxial or other). (Block 1402) Pattern graphene layer either before or after transferring to the (001)Si wafer/substrate to define features and areas and, in some embodiments, permit CMOS circuits to be combined, incorporated, integrated, etc. into/with the GaN-based materials grown on (001)Si. (Block 1404) Transfer graphene layer to clean and prepped prefabricated/fabricated CMOS and/or other Si devices and structures (e.g., bipolar, DMOS, BCD, etc., combinations of these, etc.) on (001)Si wafer/substrate. (Block 1406) Grow buffer layer (e.g., AlN, N+ AlGaN, etc.) using graphene as template on the (001)Si wafer/substrate. (Block 1408) Grow stress-mitigating/stress reduction/stress adjustment layer. (Block 1410) Grow for example GaN/InGaN/GaN heterostructures and multi-quantum and n-type and p-type doped GaN and AlGaN films to fabricate the desired device structure. (Block 1412) Perform back end processing as needed to complete the devices, structures, circuits, system on board etc. (Block 1414) Dice wafer/substrate to form dies, or other structures including system on board, chip on board, micro-LED, nano-LED, mini-LED, etc. (Block 1416)

While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention.

What is claimed is:

1. A semiconductor device, comprising:
a silicon (001) substrate;
a graphene layer on the silicon (001) substrate, wherein the graphene layer is synthesized without a metallic catalyst; and
a gallium nitride-based layer over the graphene layer.

2. A method for growing a gallium nitride layer on silicon, comprising:
depositing an amorphous carbon layer on a silicon substrate;
depositing a nickel layer on the amorphous carbon layer;
heating and quenching to convert the amorphous carbon layer and the nickel layer to a graphene layer and a Ni³C layer;
vaporizing the Ni³C layer to expose the graphene layer; and
synthesizing the gallium nitride layer on the graphene layer.

3. The method of claim 2, further comprising applying a nitrogen doping to the graphene layer.

4. The method of claim 2, further comprising applying an ammonia treatment to the graphene layer.

5. The method of claim 2, wherein the Ni³C layer is vaporized by heating.

6. The method of claim 2, further comprising depositing at least one doped gallium nitride layer.

7. A method for growing a gallium nitride layer on silicon, comprising:
preparing a graphene layer;
transferring the graphene layer to a silicon substrate;
growing a buffer layer on the graphene layer, wherein the graphene layer acts as a template for the buffer layer growth; and
growing the gallium nitride layer on the buffer layer.

8. The method of claim 7, wherein the silicon substrate comprises an Si(001) substrate.

9. The method of claim 7, wherein the buffer layer comprises an AlN layer.

10. The method of claim 7, wherein the buffer layer comprises an N+ layer.

11. The method of claim 7, wherein the buffer layer comprises an AlGaN layer.

12. The method of claim 7, further comprising growing a stress management layer on the buffer layer.

13. The method of claim 7, wherein growing the gallium nitride layer on the buffer layer comprises growing GaN heterostructures.

14. The method of claim 7, wherein growing the gallium nitride layer on the buffer layer comprises growing InGaN heterostructures.

15. The method of claim 7, wherein growing the gallium nitride layer on the buffer layer comprises growing GaN heterostructures.

16. The method of claim 7, wherein growing the gallium nitride layer on the buffer layer comprises growing a multi-quantum well film.

17. The method of claim 7, wherein growing the gallium nitride layer on the buffer layer comprises growing an n-type GaN film.

18. The method of claim 7, wherein growing the gallium nitride layer on the buffer layer comprises growing a p-type doped GaN film.

19. The method of claim 7, wherein growing the gallium nitride layer on the buffer layer comprises growing a p-type doped AlGaN film.

20. The method of claim 7, wherein growing the gallium nitride layer on the buffer layer comprises growing an n-type doped AlGaN film.
